(19) United States
(12) Patent Application Publication
(10) Pub. No.: US 2018/0031637 A1
(43) Pub. Date: Feb. 1, 2018

(54) BATTERY TESTING DEVICE AND METHOD THEREOF

(71) Applicant: CHROMA ATE INC., Taoyuan (TW)

(72) Inventor: Chih-Ming TSAI, Taoyuan (TW)

(21) Appl. No.: 15/598,108

(22) Filed: May 17, 2017

(30) Foreign Application Priority Data
Jul. 27, 2016 (TW) 105123771

(51) Int. Cl. G01R 31/36; H01M 10/48

(52) U.S. Cl. CPC G01R 31/3631; H01M 10/48; G01R 31/3648

(57) ABSTRACT

A battery testing device includes a power supply, a voltmeter, a galvanometer, a differential circuit and an analyzer. The power supply is configured to provide a constant-current signal or a constant-voltage signal to a subject battery. The voltmeter is configured to detect a voltage waveform generated by the subject battery when the power supply provides the constant-current signal to the subject battery. When a voltage value of the voltage waveform achieves a threshold voltage value, the power supply switches to provide the constant-voltage signal to the subject battery. The galvanometer is configured to detect a current waveform generated by the subject battery. The differential circuit processes the voltage waveform and the current waveform by a second-order differential. The analyzer determines a testing result of the subject battery according to the processed voltage waveform and the processed current waveform.

### CROSS-REFERENCE TO RELATED APPLICATIONS

This non-provisional application claims priority under 35 U.S.C. §119(a) on Patent Application No(s). 105123771 filed in Taiwan R.O.C. on Jul. 27, 2016, the entire contents of which are hereby incorporated by reference.

### BACKGROUND

### Technical Field

This disclosure relates to a battery testing device and a method thereof, and particularly to a battery testing device and a method thereof which processes a voltage waveform and a current waveform of a subject battery by second-order differential.

### Related Art

A battery usually includes a battery core, a cell shell and an electric power board. The battery core includes electrodes, electrolyte, an isolating film and a pot. With respect to a lithium battery, the isolating film is disposed between the positive electrode and the negative electrode, and these three components are wound together to form a jelly roll. The electrolyte serves as a transmission medium for the lithium ions in the lithium battery. When the lithium battery is charged or discharged, the lithium ions flow through the isolating film to the positive electrode or the negative electrode via the electrolyte.

In the manufacturing process of winding the isolating film, positive electrode and negative electrode together to form the jelly roll, the burr of a raw material or an exterior object may lead to a thinned isolating film usually results in an insufficient distance between the positive electrode and negative electrode. When the distance between the positive electrode and negative electrode is insufficient, the capacitance, resistance, withstand voltage or other characteristics of the battery may be affected, thus the outgoing quality of the battery may be decreased.

### SUMMARY

This disclosure provides a battery testing device and a method thereof.

According to one or more embodiments of this disclosure, a method for testing a battery includes: providing a constant-current signal to a subject battery; detecting a voltage waveform generated by the subject battery provided with the constant-current signal; switching to a constant-voltage signal to provide the subject battery with the constant-voltage signal when a voltage value of the voltage waveform generated by the subject battery achieves a threshold voltage value; detecting a current waveform generated by the subject battery provided with the constant-voltage signal; processing the voltage waveform and the current waveform by second-order differential to obtain a processed voltage waveform and a processed current waveform respectively; and determining a testing result of the subject battery according to the processed voltage waveform and the processed current waveform.

According to one or more embodiments of this disclosure, a battery testing device includes a power supply, a voltmeter, a galvanometer, a differential circuit and an analyzer. The power supply is configured to electrically connect to a subject battery, and to provide a constant-current signal or a constant-voltage signal to the subject battery. The voltmeter is configured to electrically connect to the subject battery and to detect a voltage waveform generated by the subject battery when the power supply provides the constant-current signal to the subject battery. The galvanometer is configured to electrically connect to the subject battery, and to detect a current waveform generated by the subject battery when a voltage value of the voltage waveform achieves a threshold voltage value and the power supply switches to provide the constant-voltage signal to the subject battery. The differential circuit is electrically connected to the voltmeter and the galvanometer, and processes the voltage waveform and the current waveform by a second-order differential to obtain a processed voltage waveform and a processed current waveform respectively. The analyzer is electrically connected to the differential circuit, and determines a testing result of the subject battery according to the processed voltage waveform and the processed current waveform.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a functional block diagram of a battery testing device in an embodiment of this disclosure;

FIG. 2A-2C are schematic diagrams of a voltage waveform, a current waveform, and a processed voltage waveform in an embodiment of this disclosure;

FIG. 3A-3C are schematic diagrams of a voltage waveform, a current waveform, and a processed current waveform in another embodiment of this disclosure;

FIG. 4A-4C are schematic diagrams of a voltage waveform, a current waveform, and a processed voltage current waveform in yet another embodiment of this disclosure; and

FIG. 5 is a flowchart of a method for testing a battery in an embodiment of this disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

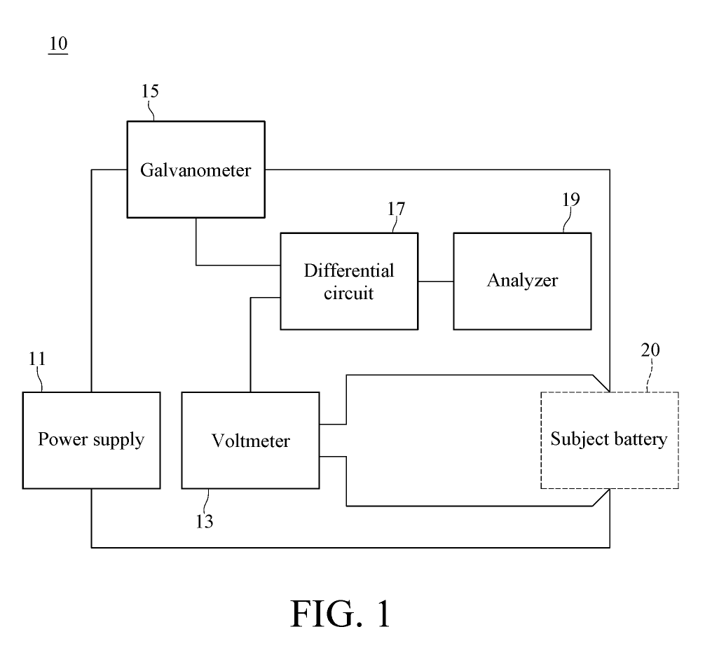

Please refer to FIG. 1. FIG. 1 is a functional block diagram of a battery testing device in an embodiment of this disclosure. As shown in FIG. 1, a battery testing device 10 is configured to electrically connect to a subject battery 20 so as to examine the characteristics of the subject battery 20, such as capacitance, resistance, withstand voltage and so on. The battery testing device 10 includes a power supply 11, a voltmeter 13, a galvanometer 15, a differential circuit 17 and an analyzer 19. For example and not thus limited, the subject battery 20 may be the final product of a battery, a battery core, a jelly roll of a battery product or other battery-related subjects.

The power supply 11 is configured to respectively and electrically connect to the positive electrode and negative electrode of the subject battery 20, and to supply a constant-current signal or a constant-voltage signal to the subject battery 20. The voltmeter 13 and the galvanometer 15 are configured to electrically connect to the subject battery 20, and to respectively detect the voltage waveform and the current waveform generated by the subject battery 20. In an embodiment, the voltmeter 13 connects to the subject battery 20 in parallel, and the galvanometer 15 and the power supply 11 connect to subject battery 20 in series. This disclosure does not intend to limit the connection scheme of these components.

The power supply 11 charges the subject battery 20 by switching between a constant-current mode and a constant-voltage mode. In the constant-current mode, the power supply 11 provides a constant-current signal to the subject battery 20 to charge the subject battery 20 according to the constant-current signal. When the subject battery 20 is charged by the constant-current signal, the voltage difference between the positive electrode and negative electrode of the subject battery 20 increases together with the amount of electric charges stored inside the subject battery 20. The voltmeter 13 detects a voltage waveform between the positive electrode and the negative electrode, and then transmits the voltage waveform to the differential circuit 17.

When the voltage value of the voltage waveform generated by the subject battery 20 achieves a threshold voltage value, the battery testing device 10 enters a constant-voltage period. In the constant-voltage period, the power supply 11 switches the constant-current signal provided for the subject battery 20 to a constant-voltage signal. Namely, the power supply 11 provides the subject battery 20 with the constant-voltage signal, so that the voltage difference between the positive electrode and negative electrode of the subject battery 20 is kept near a constant value. The galvanometer 15 detects a current waveform generated by the subject battery 20, and then transmits the current waveform to the differential circuit 17. In an embodiment, the galvanometer 15 detects the current in a loop circuit between the subject battery 20 and the power supply 11.

The differential circuit 17 is electrically connected to the voltmeter 13, the galvanometer 15 and the analyzer 19. The differential circuit 17 obtains the voltage waveform detected by the voltmeter 13 when the constant-current signal is provided to the subject battery 20, and obtains the current waveform detected by the galvanometer 15 when the constant-voltage signal is provided to the subject battery 20. In other words, the differential circuit 17 switches between the constant-current mode and the constant-voltage mode. In the constant-current mode, the differential circuit 17 obtains the voltage waveform of the subject battery 20. In the constant-voltage mode, the differential circuit 17 switches to obtaining the current waveform of the subject battery 20. The differential circuit 17 processes the voltage waveform and the current waveform by second-order differential, so that if there is an abnormal curve in the voltage waveform or the current waveform, the abnormal curve may be magnified in the processed voltage waveform or the processed current waveform. In the processed voltage or the processed current waveform, the abnormal curve is shown as a pulse with a narrow width and a large variation range, or is shown as another type of waveform which is easily to be identified. The processed voltage waveform and the processed current waveform are transmitted to the analyzer 19 for analysis. The analyzer 19 determines a testing result of the subject battery 20 according to the processed voltage waveform and the processed current waveform. For example, the analyzer 19 is a computer or other device capable of analyzing the processed voltage waveform and the processed current waveform. This disclosure does not intend to limit the type of the analyzer 19.

In practice, the power supply 11 determines whether to switch for providing the constant-voltage signal to the subject battery 20 based on the threshold voltage value. The threshold voltage value is related to the capacitance of a normal battery which is the same type as the subject battery 20, the maximum amount of electric charges that can be stored in the normal battery or other adequate basis. In an embodiment, the threshold voltage value is the voltage difference between two electrodes of the normal battery wherein the voltage difference is detected when the amount of electric charges stored in the normal battery achieves the maximum amount.

With respect to a jelly roll of a battery serving as the subject battery 20 to be tested, the predetermined capacitance of the jelly roll is decided based on the materials of the positive electrode, negative electrode and isolating film, the distance between the positive electrode and negative electrode, the ion concentration of the electrolyte or other factors. The predetermined capacitance indicates the maximum amount of the electric charges which can be stored in the jelly roll. The threshold voltage value can be the voltage difference between the positive electrode and negative electrode of a normal jelly roll, with the voltage difference detected when the normal jelly roll has charged by the constant-current signal until the amount of the electric charges stored in the normal jelly roll achieves the maximum amount. Therefore, in an embodiment, when a subject battery 20 is charged by a constant-current signal but the voltage value of the voltage waveform generated by the subject battery 20 cannot achieve the threshold voltage value, the capacitance of the subject battery 20 is not matched to the predetermined capacitance so that the subject battery 20 is determined as a defective product.

Due to the burr of a raw material or an exterior object mixed during the manufacturing process, the distance between the positive electrode and negative electrode of the subject battery 20 may be insufficient; namely, the distance between the two electrodes of the subject battery 20 is shorter than that of a normal battery. Therefore, when the subject battery 20 with the insufficient distance is provided with a constant-current signal, the voltage waveform generated by the subject battery 20 has an abnormal curve. The differential circuit 17 processes the voltage waveform by the second-order differential. In the processed voltage waveform, a pulse is caused by the abnormal curve in the voltage waveform. By identifying a variation range of a pulse in the processed voltage waveform, the analyzer may easily determine the testing result of the subject battery 20.

Similarly, when subject battery 20 with the insufficient distance is provided with a constant-voltage signal, the current waveform generated by the subject battery 20 also has an abnormal curve. The differential circuit 17 processes the current waveform by the second-order differential. In the processed current waveform, a pulse is caused by the abnormal curve in the current waveform. The analyzer 19 may easily determine the testing result of the subject battery 20 according to the processed current waveform.

In an embodiment, when the voltage value of the voltage waveform generated by a jelly roll (as the subject battery 20) and detected by the voltmeter 13 achieves the threshold voltage, the voltmeter 13 instructs the power supply 11 to switch the mode. The voltmeter 13 is also capable of instructing the power supply 11 to stop or postpone providing the constant-current signal to the jelly roll before the voltage value of the voltage waveform achieves the threshold voltage, in order to avoid the overcharge of the jelly roll. In another embodiment, another type of processor can be included in the battery testing device 10 for determining whether the voltage value of the voltage waveform generated by the jelly roll achieves the threshold voltage value, and for instructing the power supply 11 to switch the mode; it's not limited in this disclosure.

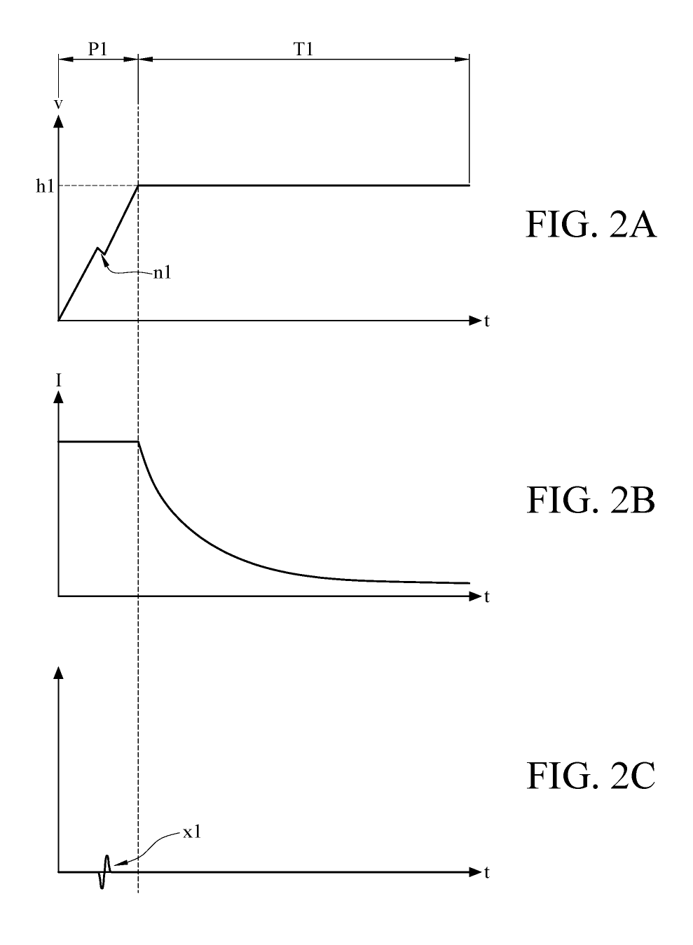

Afterwards, a number of current waveforms, voltage waveforms, a processed voltage waveforms and a processed current waveforms are exemplified. Please refer to FIG. 1 and FIG. 2A-2C. FIG. 2A-2C are schematic diagrams of a voltage waveform, a current waveform and a processed voltage waveform in an embodiment of this disclosure. As shown in the figures, in a constant-current period P1, the power supply 11 provides a constant-current signal to a subject battery 20, and the voltmeter 13 detects the voltage waveform generated by the subject battery 20. As shown in the FIG. 2A, when the voltage value of the voltage waveform generated by the subject battery 20 achieves a threshold voltage h1, the battery testing device 10 switches to the constant-voltage mode and enters the constant-voltage period T1. The power supply 11 switches to provide a constant-voltage signal to the subject battery 20, and the galvanometer 15 detects the current waveform generated by the subject battery 20, as shown in FIG. 2B. The differential circuit 17 processes the voltage waveform and the current waveform by the second-order differential to obtain the processed voltage waveform and the processed current waveform. FIG. 2C shows the processed voltage waveform. The analyzer 19 determines a testing result of the subject battery 20 according to the processed voltage waveform and the processed current waveform.

More specifically, in the constant-current period P1, the voltage difference between the positive electrode and negative electrode of the subject battery 20 increases with the amount of electric charges stored inside the subject battery 20. When the distance between the positive electrode and negative electrode of the subject battery 20 is insufficient, the voltage waveform generated by the subject battery 20 has an abnormal curve n1 during the constant-current period P1. For example, the abnormal curve n1 includes an abnormal decrease of the voltage value due to an abnormal discharge, an arc discharge between electrodes, a damage of the electrode or other factor. At this time, after the differential circuit 17 processed the voltage waveform by the second-order differential, the processed voltage waveform shows a pulse x1 reflecting the abnormal decrease of the voltage value. The pulse x1 is more easily to be identified than the abnormal curve n1 is. According to the pulse x1, the analyzer 19 is capable of determining whether the abnormal decrease of the voltage value of the voltage waveform generated by the subject battery 20 falls in an allowable range. In practice, the variation range of the pulse x1 is related to the abnormal decreasing of the voltage value of the voltage waveform. According to the variation range of the pulse x1, the analyzer 19 determines the condition of the electric charges stored in the subject battery 20 stores electric charges as the subject battery 20 being charged. In other words, the voltage waveform of the subject battery 20 is related to the capacitance of the subject battery 20.

In an embodiment, when the analyzer 19 determines that the abnormal decrease of the voltage value of the voltage waveform of the subject battery 20 exceeds the allowable range, the analyzer 19 determines the subject battery 20 as a defective product. For example, an abnormal discharge happens during charging because the distance between the positive electrode and negative electrode of the subject battery 20 is too short. At this time, the subject battery 20 is determined as a defective product. In another embodiment, when the voltage value of the voltage waveform generated by the subject battery 20 cannot achieves the threshold voltage due to the damage of the subject battery 20 caused by an abnormal discharge or another factor, the subject battery 20 is determined as a defective product, and the power supply 11 won't enter the constant-voltage period T1. The power supply 11 does not provide the constant-voltage signal to the subject battery 20 of which the voltage value does not achieve the threshold voltage value.

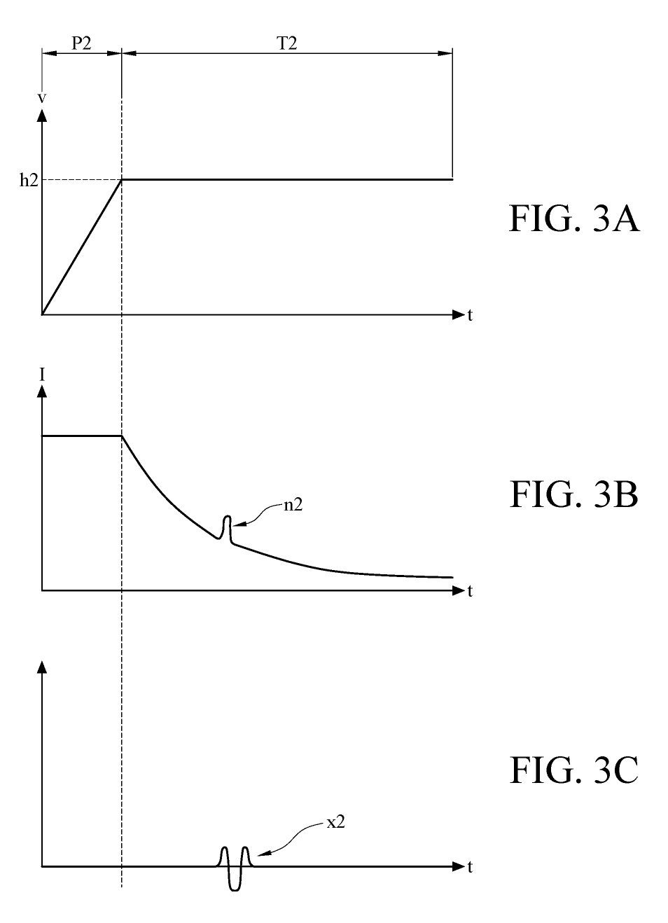

Afterwards, please refer to FIG. 1 and FIG. 3A-3C. FIG. 3A-3C are schematic diagrams of a voltage waveform, a current waveform and a processed current waveform in another embodiment of this disclosure. As shown in the figures, in a constant-current period P2, the power supply 11 provides a constant-current signal to a subject battery 20, and the voltmeter 13 detects the voltage waveform generated by the subject battery 20. When the voltage value of the voltage waveform generated by the subject battery 20 achieves a threshold voltage h2, the battery testing device 10 switches to the constant-voltage mode and enters the constant-voltage period T2. The power supply 11 switches to provide a constant-voltage signal to the subject battery 20, and the galvanometer 15 detects the current waveform generated by the subject battery 20.

In the constant-voltage period T2, a constant-voltage signal is applied to the positive electrode and negative electrode of the subject battery 20. For example, the voltage value of the constant-voltage signal is set equal to the threshold voltage value. The current in a loop circuit between the subject battery 20 and the power supply 11 decreases with the amount of the electric charges stored in the subject battery 20. When the distance between the positive electrode and negative electrode of the subject battery 20 is insufficient, the current waveform of the subject battery 20 in the constant-voltage period T2 has an abnormal curve n2. For example, the abnormal curve n2 includes an abnormal increase of the current value due to an abnormal discharge, an arc discharge between electrodes, a damage of the electrode or other factor. At this time, after the differential circuit 17 processed the current waveform by the second-order differential, the processed current waveform shows a pulse x2 reflecting the abnormal increase of the current value of the current waveform. The pulse x2 is more easily to be identified than the abnormal curve n2 is. According to the pulse x2, the analyzer 19 is capable of determining whether the abnormal increase of the current value of the current waveform generated by the subject battery 20 falls in an allowable range. In practice, the variation range of the pulse x2 is related to the abnormal increasing of the current value of the current waveform. According to the variation range of the pulse x2, the analyzer 19 determines the condition of self-discharging of the subject battery 20 in the constant-voltage period T2. In other words, the decreasing rate of the current value of the current waveform of the subject battery 20 in the constant-voltage period T2 is related to an equivalent resistor of the subject battery 20.

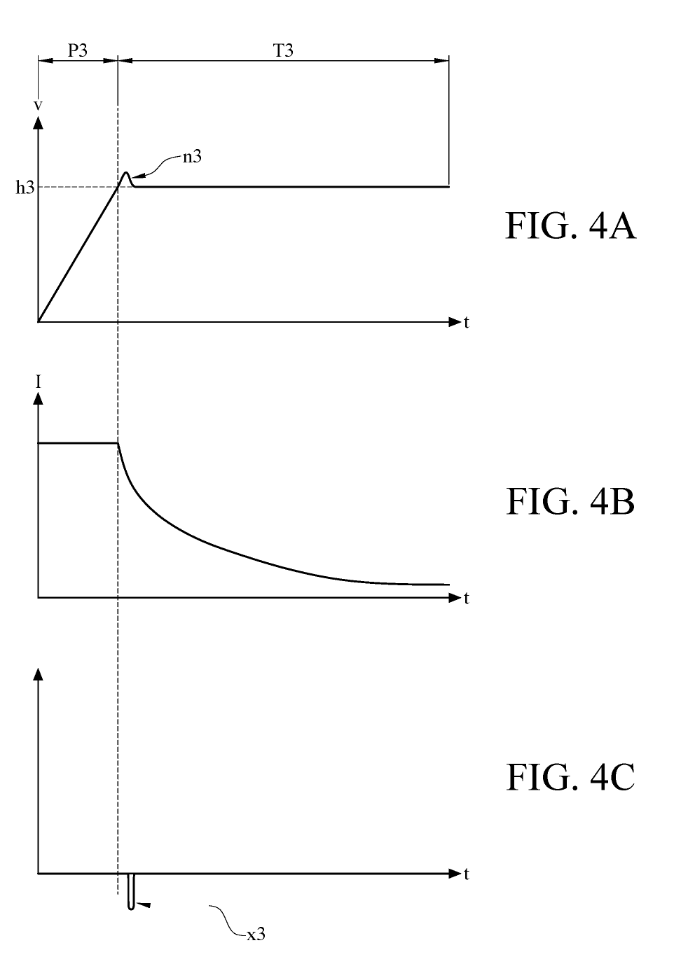

Please refer to FIG. 1 and FIG. 4A-4C. FIG. 4A-4C are schematic diagrams of a voltage waveform, a current waveform and a processed voltage waveform in yet another waveform of this disclosure. As shown in the figures, in a constant-current period P3, the power supply 11 provides a constant-current signal to a subject battery 20 for charging. When the voltage value of the voltage waveform of the subject battery 20 achieves the threshold voltage value, an overcharge of the subject battery 20 might happen although the power supply 11 has already stop or postpone providing the constant-current signal to the subject battery 20. The overcharge is shown as an overcharge curve in FIG. 4A. When the subject battery 20 is overcharged, the processed voltage waveform has a pulse x3 reflecting the overcharge, with the processed voltage obtained by processing the voltage waveform by the second-order differential by the differential circuit 17. In other words, when the analyzer 19 receives the processed voltage waveform from the differential circuit 17, the analyzer 19 is capable of determining a testing result according to the pulse in the processed voltage waveform. If the pulse in the processed voltage waveform is a positive pulse, the analyzer 19 determines that the voltage value of the voltage waveform increases abnormally. If the pulse in the processed voltage waveform is a negative pulse, the analyzer 19 determines that the subject battery 20 is overcharged. When the variation range of the negative plus x3 in the processed voltage waveform falls into an allowable range, the overcharge of the subject battery 20 can be ignored.

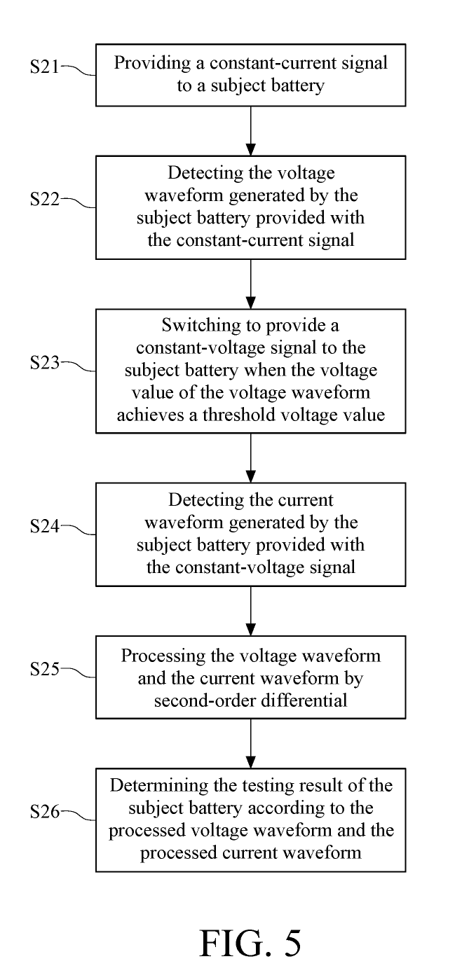

To explain a method for the battery testing device 10 to test a subject battery 20 more specifically, please refer to FIG. 1 and FIG. 5. FIG. 5 is a flowchart of a method for a battery testing in an embodiment of this disclosure. As shown in the figures, in step S21, the power supply 11 provides a constant-current signal to the subject battery 20. In step S22, the voltmeter 13 detects the voltage waveform generated by the subject battery 20, with the battery provided with the constant-current signal. In step S23, when the voltage value of the voltage waveform generated by the subject battery 20 achieves a threshold voltage value, the power supply 11 switches to provide a constant-voltage signal to the subject battery 20. In step S24, the galvanometer 15 detects the current waveform generated by the subject battery 20, with the subject battery 20 provided with the constant-voltage signal. In step S25, the differential circuit 17 processes the voltage waveform and the current waveform by second-order differential. In step S26, the analyzer 19 determines a testing result of the subject battery 20 according to the processed voltage waveform and the processed current waveform. The practical method for the battery testing is disclosed in the aforementioned embodiments, so the related details are not repeated in this embodiment.

In view of the above description, this disclosure provides a battery testing device and a method for a battery testing. By providing a constant-current signal and switching to provide a constant-voltage signal to a subject battery to be tested when the subject battery is charged, detecting the voltage waveform generated by the subject battery when the subject battery is provided with the constant-current signal, detecting the current waveform generated by the subject battery when the subject battery is provided with the constant-voltage signal and processing the voltage waveform and the current waveform by second-order differential, an abnormal curve in the voltage waveform or the current waveform may be magnified in the processed voltage waveform or the processed current waveform, so that the analyzer may easily analysis the voltage variation and the current variation of the subject battery during the charging according to the processed voltage waveform and the processed current waveform. Therefore, any condition of the subject battery during the charging may be handled, and damage, carbonization of the isolating film or other situation occurring during the charging of the subject battery and resulting in the reduction of the outgoing quality of the subject battery may be avoided.

What is claimed is:

1. A method for testing a battery, comprising:
providing a constant-current signal to a subject battery;
detecting a voltage waveform generated by the subject battery provided with the constant-current signal;
switching a constant-voltage signal to the subject battery when a voltage value of the voltage waveform generated by the subject battery achieves a threshold voltage value;
detecting a current waveform generated by the subject battery provided with the constant-voltage signal;
processing the voltage waveform and the current waveform by second-order differential to obtain a processed voltage waveform and a processed current waveform respectively; and
determining a testing result of the subject battery according to the processed voltage waveform and the processed current waveform.

2. The method according to claim 1, further comprising setting the threshold voltage as a voltage value of the constant-voltage signal when the voltage value of the voltage waveform achieves the threshold voltage value.

3. The method according to claim 1, wherein the voltage waveform of the subject battery is related to a capacitance of the subject battery, and the current waveform of the subject battery is related to an equivalent resistor of the subject battery.

4. The method according to claim 3, wherein determining the testing result of the subject battery comprises identifying a variation range of a pulse in the processed voltage waveform, with the pulse caused by an abnormal curve in the voltage waveform obtained by detecting the voltage waveform generated by the subject battery.

5. The method according to claim 3, wherein determining the testing result of the subject battery comprises identifying a variation range of a pulse in the processed waveform, with the pulse caused by an abnormal curve in the current waveform obtained by detecting the current waveform generated by the subject battery.

6. A battery testing device for testing a subject battery, comprising:
a power supply configured to electrically connect to the subject battery, and to provide a constant-current signal or a constant-voltage signal to the subject battery;
a voltmeter configured to electrically connect to the subject battery and to detect a voltage waveform generated by the subject battery when the power supply provides the constant-current signal to the subject battery;
a galvanometer configured to electrically connect to the subject battery, and to detect a current waveform generated by the subject battery when a voltage value of the voltage waveform achieves a threshold voltage value and the power supply switches to provide the constant-voltage signal to the subject battery;
a differential circuit electrically connected to the voltmeter and the galvanometer, and processing the voltage waveform and the current waveform by a second-order differential to obtain a processed voltage waveform and a processed current waveform respectively; and
an analyzer electrically connected to the differential circuit, and determining a testing result of the subject battery according to the processed voltage waveform and the processed current waveform.

7. The battery testing device according to claim 6, wherein the power supply sets a voltage value of the constant-voltage signal as the threshold voltage value.

8. The battery testing device according to claim 6, wherein the voltage waveform of the subject battery is related to a capacitance of the subject battery and the current waveform of the subject battery is related to an equivalent resistor of the subject battery.

9. The battery testing device according to claim 8, wherein the testing result of the subject battery is related to a variation range of a pulse in the processed voltage waveform, and the pulse is caused by an abnormal curve in the voltage waveform.

10. The battery testing device according to claim 8, wherein the testing result of the subject battery is related to a variation range of a pulse in the processed current waveform, and the pulse is caused by an abnormal curve in the current waveform.
